(19) United States
(12) Patent Application Publication
(10) Pub. No.: US 2025/0158601 A1
(43) Pub. Date: May 15, 2025

(54) SUPERCONDUCTING DATA ALIGNMENT SYSTEM

(71) Applicant: NORTHROP GRUMMAN SYSTEMS CORPORATION, FALLS CHURCH, VA (US)

(72) Inventor: SEAN ASHLEY LINDSAY, MILLERSVILLE, MD (US)

(21) Appl. No.: 18/509,062

(22) Filed: Nov. 14, 2023

(51) Int. Cl. H03K 3/38; H03K 5/00; H03K 5/01

(52) U.S. Cl. CPC H03K 3/38; H03K 5/01; H03K 2005/00286

(57) ABSTRACT

One example includes a data alignment system. The system includes a first coupling circuit configured to receive a return-to-zero (RTZ) input pulse and to generate a first single flux quantum (SFQ) pulse in response to the RTZ input pulse being aligned with a phase window of a first clock signal. The system also includes a second coupling circuit configured to receive the RTZ input pulse and to generate a second SFQ pulse in response to the RTZ input pulse being aligned with a phase window of a second clock signal, the first and second clock signals being opposite in phase. The system further includes an alignment circuit that is configured to generate an output SFQ pulse that is aligned to one of the first and second clock signals in response to receiving at least one of the first and second SFQ pulses.

### GOVERNMENT INTEREST

The invention was made under Government Contract. Therefore, the U.S. Government has rights to the invention as specified in that contract.

### TECHNICAL FIELD

The present invention relates generally to computer systems, and specifically to a superconducting data alignment system.

### BACKGROUND

Superconducting digital technology has provided computing and/or communications resources that benefit from unprecedented high speed, low power dissipation, and low operating temperature. Superconducting digital technology has been developed as an alternative to complementary metal oxide semiconductor (CMOS) technology, and typically comprises superconductor based single flux superconducting circuitry, utilizing superconducting Josephson junctions, and can exhibit typical signal power dissipation of less than 1 nW (nanowatt) per active device at a typical data rate of 20 Gb/s (gigabytes/second) or greater, and can operate at temperatures of around 4 or fewer Kelvin.

Some superconducting circuits implement bias signals to trigger Josephson junctions to propagate single flux quantum (SFQ) pulses. Like traditional CMOS technology, data can be transferred in superconducting circuits based on an oscillating clock signal. Therefore, logic operations and other time-dependent signal transfer can occur in superconducting circuits based on the clock signal. One such example of superconducting circuits is reciprocal quantum logic (RQL), in which an AC clock signal provides the bias signals to trigger and untrigger the Josephson junctions, such as in a sequential sequence that is timed to specific phases of the AC clock signal. While it is simple to align data propagation in a given chip that is supplied with a clock signal, signal transfer between integrated circuits or from room temperature circuits to cryogenic temperature superconducting circuits can present challenges for time alignment.

### SUMMARY

One example includes a data alignment system. The system includes a first coupling circuit configured to receive a return-to-zero (RTZ) input pulse and to generate a first single flux quantum (SFQ) pulse in response to the RTZ input pulse being aligned with a phase window of a first clock signal. The system also includes a second coupling circuit configured to receive the RTZ input pulse and to generate a second SFQ pulse in response to the RTZ input pulse being aligned with a phase window of a second clock signal, the first and second clock signals being opposite in phase. The system further includes an alignment circuit that is configured to generate an output SFQ pulse that is aligned to one of the first and second clock signals in response to receiving at least one of the first and second SFQ pulses.

Another example includes a method for aligning data to a defined phase of a clock signal at an input of a superconducting circuit. The method includes providing a first phase window of a clock signal to a first coupling circuit and providing a second phase window of the clock signal to a second coupling circuit, the second phase window being opposite in phase relative to the first phase window. The method also includes providing a RTZ input pulse to each of the first and second coupling circuits to generate at least one of a first SFQ pulse from the first coupling circuit and a second SFQ pulse from the second coupling circuit. The method further includes providing the clock signal to an alignment circuit to generate an output SFQ pulse that is aligned to the clock signal in response to receiving at least one of the first and second SFQ pulses.

Another example includes a reciprocal quantum logic (RQL) circuit system. The system includes a data alignment system. The data alignment system includes a first coupling circuit configured to receive a RTZ input pulse and to generate a first RQL pulse in response to the RTZ input pulse being aligned with a first phase window of an RQL clock signal. The data alignment circuit also includes a second coupling circuit configured to receive the RTZ input pulse and to generate a second RQL pulse in response to the RTZ input pulse being aligned with a second phase window of the RQL clock signal. The first and second phase windows can be opposite in phase. The data alignment system further includes an alignment circuit that is configured to generate an output RQL pulse that is aligned to the RQL clock signal in response to receiving at least one of the first and second RQL pulses. The system further includes an RQL superconducting circuit that operates based on the RQL clock signal, wherein the RQL superconducting circuit receives the output RQL pulse aligned to a defined phase of the RQL clock signal at an input.

### BRIEF DESCRIPTION OF THE DRAWINGS

FIG. 1 illustrates an example of a superconducting data alignment system.

FIG. 2 illustrates an example of a phase diagram.

FIG. 3 illustrates an example of coupling circuits.

FIG. 4 illustrates an example of an alignment circuit.

FIG. 5 illustrates an example of a reciprocal quantum logic superconducting circuit system.

FIG. 6 illustrates an example of a method for aligning an SFQ pulse to a defined phase of a clock signal at an input of a superconducting circuit.

### DETAILED DESCRIPTION

The present invention relates generally to computer systems, and specifically to a superconducting data alignment system. The superconducting data alignment system can be implemented in any of a variety of superconducting circuit systems to align a return-to-zero (RTZ) input pulse to a clock signal associated with the superconducting circuit system. For example, the RTZ input pulse can be provided from another circuit, such as another superconducting integrated circuit (IC), such as via a passive transmission line (PTL), or from a complementary metal oxide semiconductor (CMOS) circuit that resides in room temperature environment to the superconducting circuit system in cryogenic temperature. Therefore, the input data to the superconducting circuit can be aligned to the clock signal to provide for data propagation in the superconducting circuit.

The superconducting data alignment system includes a first coupling circuit and a second coupling circuit. The first coupling circuit is configured to receive the RTZ input pulse and a first clock signal and the second coupling circuit is configured to receive the RTZ input pulse and a second clock signal having an opposite phase relative to the first clock signal. As an example, the first and second clock signals can include opposite phase windows (e.g., 180° out-of-phase with each other) corresponding to sufficient bias to trigger a Josephson junction in the respective first and second coupling circuits in response to the RTZ input pulse. For example, the phase windows can include overlapping portions, such as at the beginning and end of each of the phase windows, such that the RTZ input pulse will trigger the Josephson junction in one or both of the first and second coupling circuits, regardless of the phase on which the RTZ input pulse is provided. As an example, the first and second clock signals can correspond to separate phase windows of the same clock signal (e.g., provided in opposite polarity through transformers), such as one of the in-phase and the quadrature phase components of a reciprocal quantum logic (RQL) clock signal.

The first and second coupling circuits are thus configured to generate at least one of a respective first and second single flux quantum (SFQ) pulse in response to the RTZ input pulse and the clock signal(s). As described herein, the term SFQ pulse describes a fluxon provided from a Josephson junction, and can include an RQL pulse arranged as a positive fluxon followed by a negative fluxon. The first and/or second SFQ pulses are provided to an alignment circuit that is configured to generate an output SFQ pulse that is aligned to a clock signal, such as one of the first and second clock signals (e.g., the RQL clock signal). As an example, the alignment circuit can include first and second signal paths that can propagate the respective first and second SFQ pulses to a logic OR gate to provide the output pulse. As another example, in response to the alignment circuit receiving both the first and second SFQ pulses, as described in greater detail herein, the alignment circuit can be configured to delay the second SFQ pulse relative to the first SFQ pulse to phase-align the first and second SFQ pulses to reject the first SFQ pulse, thereby generating the output SFQ pulse based on the second SFQ pulse. The first and/or second SFQ pulses can be propagated in the alignment circuit by Josephson transmission lines, such that the output SFQ pulse can be generated and output from the superconducting data alignment system as phase-aligned to the clock signal.

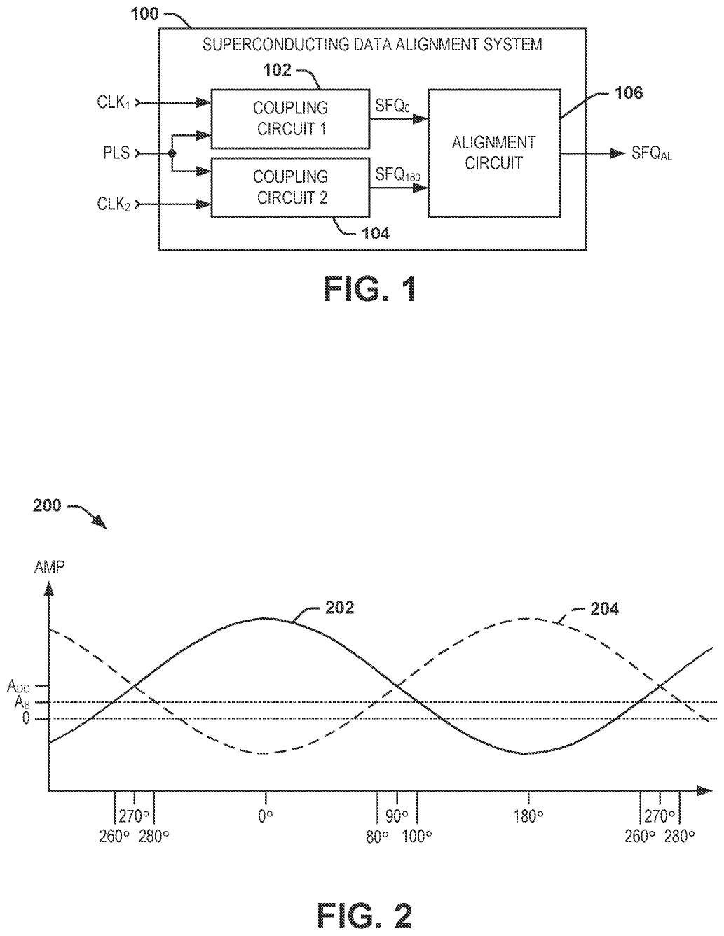

FIG. 1 illustrates an example of a superconducting data alignment system 100. The superconducting data alignment system 100 can be implemented in any of a variety of superconducting circuit systems to align a return-to-zero (RTZ) input pulse, demonstrated in the example of FIG. 1 as a signal PLS, to a clock signal, such as associated with the superconducting circuit system. In the example of FIG. 1, the clock signal is demonstrated as a first clock signal CLK₁ and a second clock signal CLK₂. As an example, the first and second clock signals CLK₁ and CLK₂ can correspond to opposite phases of the same clock signal, such as a reciprocal quantum logic (RQL) clock signal.

As an example, the RTZ input pulse PLS can be provided as an input to the superconducting data alignment system from another circuit. As an example, the other circuit can be another superconducting circuit, such as from another superconducting integrated circuit (IC) via a passive transmission line (PTL). As another example, the RTZ input pulse PLS can be provided from a complementary metal oxide semiconductor (CMOS) circuit that resides in room temperature environment, such that the RTZ input pulse PLS is provided through a thermal barrier to the superconducting circuit system in cryogenic temperature. Therefore, the input data provided via the RTZ input pulse PLS provided to the superconducting data alignment system can be aligned to at least one of the clock signals CLK₁ and CLK₂ to provide for data propagation in an associated superconducting circuit.

The superconducting data alignment system 100 includes a first coupling circuit 102 and a second coupling circuit 104. The first coupling circuit 102 is configured to receive the RTZ input pulse PLS and a first clock signal CLK₁, and the second coupling circuit 104 is configured to receive the RTZ input pulse PLS and a second clock signal CLK₁ having an opposite phase relative to the first clock signal CLK₁. As an example, the first and second clock signals CLK₁ and CLK₂ can include opposite phase windows (e.g., 180° out-of-phase with each other) corresponding to sufficient bias to trigger a Josephson junction in the respective first and second coupling circuits 102 and 104 in response to the RTZ input pulse PLS. For example, the phase windows can include overlapping portions, such as at the beginning and end of each of the phase windows, such that the RTZ input pulse PLS triggers the Josephson junction in one or both of the first and second coupling circuits 102 and 104, regardless of the phase on which the RTZ input pulse PLS is provided. As an example, the first and second clock signals CLK₁ and CLK₂ can correspond to separate phase windows of the same clock signal (e.g., provided in opposite polarity through transformers), such as one of the in-phase and the quadrature phase components of an RQL clock signal.

In the example of FIG. 1, the first coupling circuit 102 is configured to generate a first single flux quantum (SFQ) pulse SFQ₀ in response to the RTZ input pulse PLS and the first clock signal CLK₁ triggering the associated Josephson junction of the first coupling circuit 102. Therefore, if the RTZ input pulse PLS is input to the superconducting data alignment system 100 during the phase window of the first clock signal CLK₁, then the first clock signal CLK₁ provides sufficient bias to the associated Josephson junction of the first coupling circuit 102 to trigger the Josephson junction in response to the current provided by the RTZ input pulse PLS. Similarly, the second coupling circuit 104 is configured to generate a second SFQ pulse SFQ₁₈₀ in response to the RTZ input pulse PLS and the second clock signal CLK₂ triggering the associated Josephson junction of the second coupling circuit 104. Therefore, if the RTZ input pulse PLS is input to the superconducting data alignment system 100 during the phase window of the second clock signal CLK₂, then the second clock signal CLK₂ provides sufficient bias to the associated Josephson junction of the second coupling circuit 104 to trigger the Josephson junction in response to the current provided by the RTZ input pulse PLS. To ensure that at least one of the SFQ pulses SFQ₀ and SFQ₁₈₀ are triggered, the first and second clock signals CLK₁ and CLK₂ can include overlapping portions of the respective phase windows. Therefore, if the RTZ input pulse PLS is input to the superconducting data alignment system 100 during the overlapping phase windows of the first and second clock signals CLK₁ and CLK₂, then the first coupling circuit 102 generates the first SFQ pulse SFQ₀ and the second coupling circuit 104 generates the second SFQ pulse SFQ₁₈₀ concurrently.

FIG. 2 illustrates an example of a phase diagram 200. The phase diagram 200 demonstrates a plot of amplitude AMP as a function of phase. The phase diagram 200 includes a first clock signal 202, demonstrated as having a solid line, and the second clock signal 204, demonstrated as having a dashed line. The first and second clock signals 202 and 204 can correspond, respectively, to the first and second clock signals CLK₁ and CLK₂. Therefore, reference is to be made to the examples of FIG. 1 in the following description of the example of FIG. 2.

In the example of FIG. 2, the first and second clock signals 202 and 204 are demonstrated as having an opposite phase, and are thus demonstrated as being 180° out-of-phase with respect to each other. As an example, the first and second clock signals 202 and 204 can be generated from the same clock signal, such that the second clock signal 204 can be provided based on the first clock signal 202 being provided in reverse polarity through a transformer. Also in the example of FIG. 2, the first and second clock signals 202 and 204 are demonstrated as having a DC offset relative to zero amplitude. Thus, the nodes of the first and second clock signals 202 and 204 are demonstrated as having an amplitude of ADC that is greater than zero.

The phase diagram 200 also demonstrates an amplitude AB that can correspond to a sufficient bias amplitude of the clock signals 202 and 204 for triggering the Josephson junctions of the first and second coupling circuits 102 and 104 when combined with the RTZ input pulse PLS. The sufficient bias amplitude AB thus defines a phase window of the respective clock signals 202 and 204 during which, if the RTZ input pulse PLS arrives at the superconducting data alignment system 100 in the phase window, the Josephson junction of the respective one of the first and second coupling circuits 102 and 104 triggers to provide the respective one of the first and second SFQ pulses SFQ₀ and SFQ₁₈₀.

Based on the DC offset of the amplitude of the clock signals 202 and 204, portions of the phase windows of the respective clock signals 202 and 204 that define the sufficient bias amplitude AB overlap. In the example of FIG. 2, the phase window of the first clock signal 202 is defined between the phase 260° and 100°, while the phase window of the second clock signal 204 is defined between the phase 80° and 280°. Therefore, the beginning of the phase window of the first clock signal 202 overlaps with the end of the phase window of the second clock signal between the phases 260° and 280°, and the beginning of the phase window of the second clock signal 204 overlaps with the end of the phase window of the first clock signal between the phases 80° and 100°. Because the phase windows of the clock signals 202 and 204 define sufficient amplitude to bias the Josephson junctions to trigger the respective Josephson junctions in response to the RTZ input pulse PLS, then if the RTZ input pulse PLS arrives at the superconducting data alignment system 100 during the overlapping phase portions of between 260° and 280° and between 80° and 100°, then the Josephson junctions of both of the first and second coupling circuits 102 and 104 trigger to generate the respective SFQ pulses SFQ₀ and SFQ₁₈₀. In this manner, regardless of the pulse width of the RTZ input pulse PLS and regardless of the phase of arrival of the RTZ input pulse PLS, the superconducting data alignment system 100 captures the RTZ input pulse PLS to provide phase alignment of the data associated therewith, as described herein.

Referring back to the example of FIG. 1, the superconducting data alignment system 100 also includes an alignment circuit 106. The alignment circuit 106 receives at least one of the first and second SFQ pulses SFQ₀ and SFQ₁₈₀, and is configured to generate an output SFQ pulse SFQ_{AL} that is aligned to a clock signal. As described herein, the phrase “aligned to a clock signal” describes that the output SFQ pulse SFQ_{AL} is phase-aligned to a specific phase of the clock signal, such that the output SFQ pulse SFQ_{AL} can propagate on Josephson transmission lines (JTLs) at each phase increment of the clock signal. As an example, the clock signal to which the output SFQ pulse SFQ_{AL} is aligned can be one or both of the first and second clock signals (e.g., the RQL clock signal).

As an example, the alignment circuit 106 can include first and second signal paths that can propagate the respective first and second SFQ pulses SFQ₀ and SFQ₁₈₀ to a logic OR gate to provide the output SFQ pulse SFQ_{AL}. As another example, in response to the alignment circuit 106 receiving both the first and second SFQ pulses, as described above in the example of FIG. 2, the alignment circuit 106 can be configured to delay the second SFQ pulse SFQ₁₈₀ relative to the first SFQ pulse SFQ₀ to phase-align the first and second SFQ pulses SFQ₀ and SFQ₁₈₀. For example, the first and second coupling circuits 102 and 104 can generate both of the respective first and second SFQ pulses SFQ₀ and SFQ₁₈₀ concurrently, despite the phase windows of the clock signals CLK₁ and CLK₂ being opposite phases. Therefore, the alignment circuit 106 can phase-align the SFQ pulses SFQ₀ and SFQ₁₈₀ to provide logic operations on the SFQ pulses SFQ₀ and SFQ₁₈₀ in a time-aligned manner. For example, the phase-delay of the second SFQ pulse SFQ₁₈₀ can result in the alignment circuit 106 rejecting the first SFQ pulse SFQ₀, thereby generating the output SFQ pulse SFQ_{AL} based on the second SFQ pulse SFQ₁₈₀ only. The first and/or second SFQ pulses SFQ₀ and SFQ₁₈₀ can be propagated in the alignment circuit 106 by JTLs that are aligned to the clock signal. Therefore, the output SFQ pulse SFQ_{AL} can likewise be phase-aligned to the clock signal when output from the superconducting data alignment system 100.

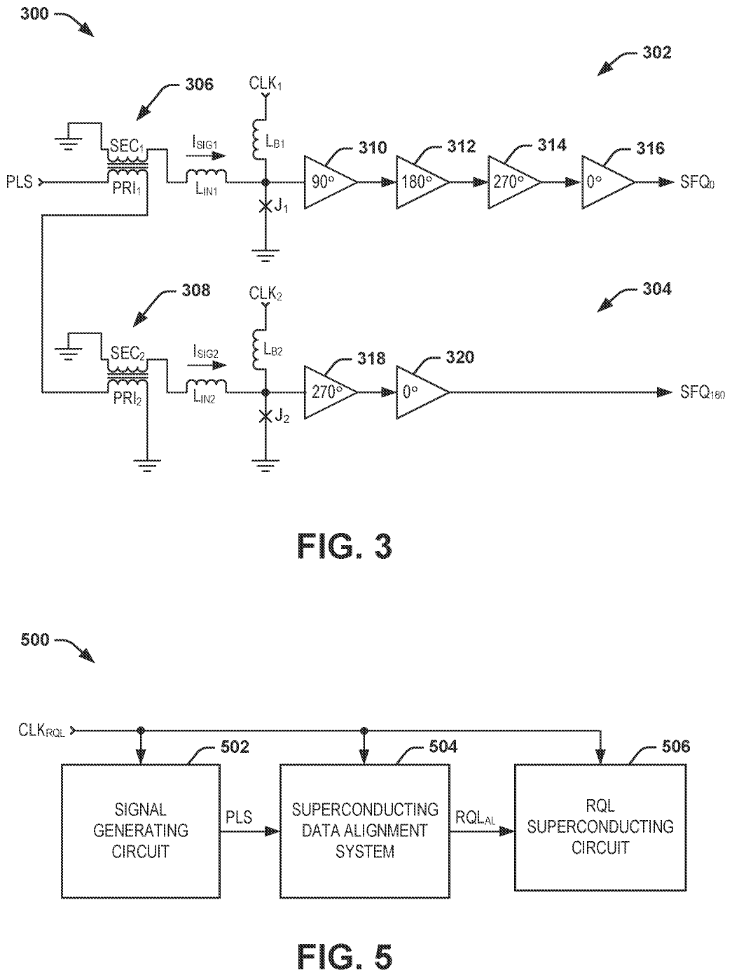

FIG. 3 illustrates an example diagram 300 of coupling circuits. The diagram 300 includes a first coupling circuit 302 and a second coupling circuit 304. The first and second coupling circuits 302 and 304 can correspond to the first and second coupling circuits 102 and 104 in the example of FIG. 1. Therefore, reference is to be made to the examples of FIGS. 1 and 2 in the following description of the example of FIG. 3.

The coupling circuits 302 and 304 are demonstrated as receiving the RTZ pulse signal PLS. In the example of FIG. 3, the RTZ pulse signal PLS is provided in series through a primary winding PRI₁ of a first transformer 306 associated with the first coupling circuit 302 and through a primary winding PRI₂ of a second transformer 308 associated with the second coupling circuit 304. Therefore, the RTZ pulse signal PLS is provided concurrently to both of the first and second coupling circuits 302 and 304. In response to the RTZ pulse signal PLS, the transformers 306 and 308 are each configured to inductively provide respective signal currents I_{SIG1} and I_{SIG2} via respective secondary windings SEC₁ and SEC₂ of the transformers 306 and 308.

The first coupling circuit 302 includes a first inductor L_{IN1}, a first Josephson junction J₁, and a first bias inductor L_{B1} through which the first clock signal CLK₁ is provided. Therefore, the first inductor L_{IN1}, the first Josephson junction J₁, and the first bias inductor L_{B1} form a JTL that is aligned to the first clock signal CLK₁, and thus 0°. The first coupling circuit 302 also includes a JTL 310 that is aligned to the 90° phase of the clock signal, a JTL 312 that is aligned to the 180° phase of the clock signal, a JTL 314 that is aligned to the 270° phase of the clock signal, and a JTL 316 that is aligned to the 0° phase of the clock signal. The JTL 316 can thus provide the first SFQ pulse SFQ₀ as an output from the first coupling circuit 302. Therefore, in response to the signal current I_{SIG1} being provided through the inductor L_{IN1} during the phase window of the first clock signal CLK₁ (e.g., from 260° to 100°, as described above in the example of FIG. 2), the first Josephson junction J₁ triggers to generate an SFQ pulse. The SFQ pulse can thus propagate through the JTLs 310, 312, 314, and 316 at each of 90° intervals of the clock signal to be provided as the first SFQ pulse SFQ₀ output from the first coupling circuit 302. As an example, the operating margins of the JTL 310 can be sufficient to capture the SFQ pulse generated by the Josephson junction J₁ throughout the entirety of the phase window of the first clock signal CLK₁.

The second coupling circuit 304 includes a second inductor L_{IN2}, a second Josephson junction J₂, and a second bias inductor L_{B2} through which the second clock signal CLK₂ is provided. Therefore, the second inductor L_{IN2}, the second Josephson junction J₂, and the second bias inductor L_{B2} form a JTL that is aligned to the second clock signal CLK₂, and thus 180°. The second coupling circuit 304 also includes a JTL 318 that is aligned to the 270° phase of the clock signal and a JTL 320 that is aligned to the 0° phase of the clock signal. The JTL 320 can thus provide the second SFQ pulse SFQ₁₈₀ as an output from the second coupling circuit 304. Therefore, in response to the signal current I_{SIG2} being provided through the inductor L_{IN2} during the phase window of the second clock signal CLK₂ (e.g., from 80° to 280°, as described above in the example of FIG. 2), the second Josephson junction J₂ triggers to generate an SFQ pulse. The SFQ pulse can thus propagate through the JTLs 318 and 320 at each of 90° intervals of the clock signal to be provided as the second SFQ pulse SFQ₁₈₀ output from the second coupling circuit 304. As an example, the operating margins of the JTL 318 can be sufficient to capture the SFQ pulse generated by the Josephson junction J₂ throughout the entirety of the phase window of the second clock signal CLK₂.

As described above in the example of FIG. 2, the phase windows of the clock signals CLK₁ and CLK₂ can overlap. Therefore, in response to the signal currents I_{SIG1} and I_{SIG2} being provided during one of the overlaps of the phase windows of the clock signals CLK₁ and CLK₂, both of the Josephson junctions J₁ and J₂ trigger to generate SFQ pulses. Based on the clock phases of the JTLs 310, 312, 314, and 316 relative to the clock phases of the JTLs 318 and 320, the first coupling circuit 302 can phase-delay the output of the first SFQ pulse SFQ₀ by one clock cycle (e.g., one period of the clock signal) relative to the output of the second SFQ pulse SFQ₁₈₀. Therefore, if both of the first and second resonators 302 and 304 generate the respective SFQ pulses SFQ₀ and SFQ₁₈₀, the SFQ pulses SFQ₀ and SFQ₁₈₀ will be aligned to the same phase as output from the respective first and second coupling circuits 302 and 304, but will be one complete clock cycle out of phase with respect to each other. In other words, the second SFQ pulse SFQ₁₈₀ will be output from the second coupling circuit 304 one complete clock cycle ahead of the first SFQ pulse SFQ₀ being output from the first coupling circuit 302.

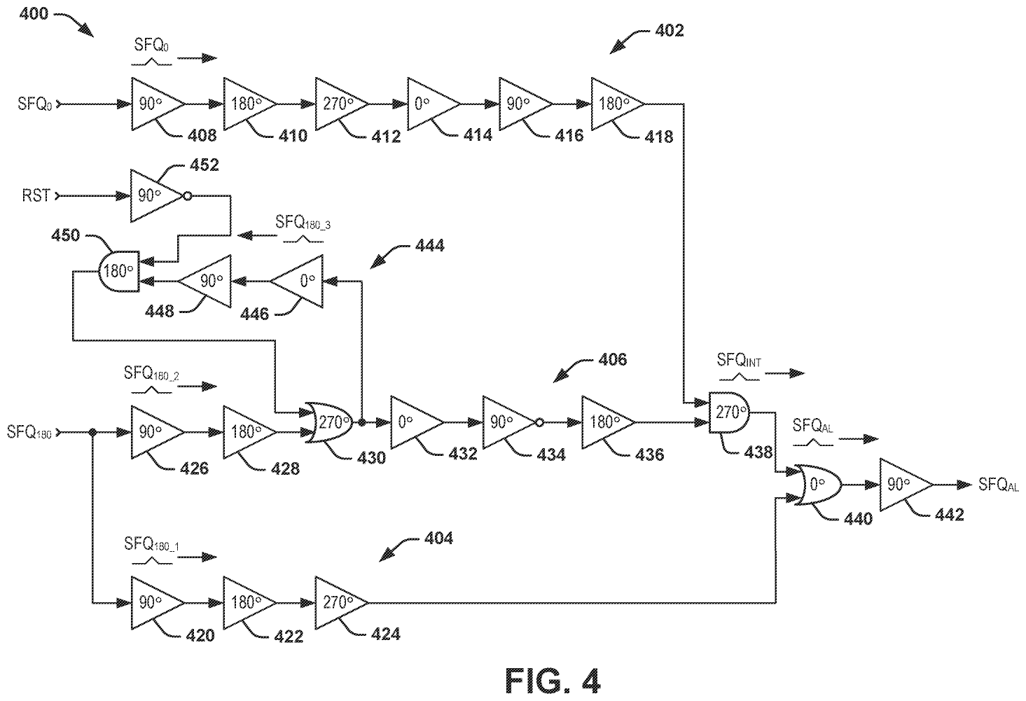

FIG. 4 illustrates an example of an alignment circuit 400. The alignment circuit 400 can correspond to the alignment circuit 106 in the example of FIG. 1. Therefore, reference is to be made to the examples of FIGS. 1-3 in the following description of the example of FIG. 4.

The alignment circuit 400 includes a first signal path 402 that propagates the first SFQ pulse SFQ₀, a second signal path 404 and a third signal path 406 that each propagate the second SFQ pulse SFQ₁₈₀. The first signal path 402 includes a JTL 408 that is aligned to the 90° phase of the clock signal, a JTL 410 that is aligned to the 180° phase of the clock signal, a JTL 412 that is aligned to the 270° phase of the clock signal, a JTL 414 that is aligned to the 0° phase of the clock signal, a JTL 416 that is aligned to the 90° phase of the clock signal, and a JTL 418 that is aligned to the 180° phase of the clock signal. The second signal path 404 includes a JTL 420 that is aligned to the 90° phase of the clock signal, a JTL 422 that is aligned to the 180° phase of the clock signal, and a JTL 424 that is aligned to the 270° phase of the clock signal. The third signal path 406 includes a JTL 426 that is aligned to the 90° phase of the clock signal, a JTL 428 that is aligned to the 180° phase of the clock signal, a logic OR gate 430 that is aligned to the 270° phase of the clock signal, a JTL 432 that is aligned to the 0° phase of the clock signal, an inverting JTL 434 that is aligned to the 90° phase of the clock signal, and a JTL 436 that is aligned to the 180° phase of the clock signal. The first and third signal paths 402 and 406 are each coupled as inputs to a logic AND gate 438 that is aligned to the 270° phase of the clock signal. The logic AND gate 438 and the JTL 424 of the second signal path 404 are each provided as inputs to a logic OR gate 440 that is aligned to the 0° phase of the clock signal. The output of the logic OR gate 440 is provided to an output JTL 442 that is aligned to the 90° phase of the clock signal, and thus provides the output SFQ pulse SFQ_{AL} aligned to the 90° phase of the clock signal.

The alignment circuit 400 also includes a latch 444 that is coupled to the third signal path 406. The latch 444 includes a JTL 446 that is aligned to the 0° phase of the clock signal and is coupled to the output of the logic OR gate 430. The latch also includes a JTL 448 that is aligned to the 90° phase of the clock signal and a logic AND gate 450 that is aligned to the 180° phase of the clock signal. The logic AND gate 450 has inputs received from the JTL 448 and from an inverting JTL 452 that is aligned to the 90° phase of the clock signal. The output of the logic AND gate 450 is provided as a second input to the logic OR gate 430. The inverting JTL 452 is provided a reset signal (“RST”) as an input, as described in greater detail herein.

With reference to FIGS. 1-3, in a first example, the RTZ pulse signal PLS arrives at the superconducting data alignment system 100 in the phase window of the first clock signal CLK₁ only (e.g., between 280° and) 80°. The RTZ pulse signal PLS thus provides the first signal current I_{SIG1} during the phase window of the first clock signal CLK₁ to trigger the first Josephson junction J₁ to generate a first signal SFQ pulse. The first signal SFQ pulse propagates through the JTLs 310, 312, 314, and 316 to be output as the first SFQ pulse SFQ₀. The first SFQ pulse SFQ₀ is thus input to the alignment circuit 400 and propagates through the JTLs 408, 410, 412, 414, 416, and 418 of the first signal path 402 to the logic AND gate 438. The absence of the second SFQ pulse SFQ₁₈₀ provides that no SFQ pulse propagates through the third signal path 406. However, the inverting JTL 434 can provide a superconducting phase or an SFQ pulse at each 90° increment of the clock signal, which can propagate through the JTL 436 to the logic AND gate 438. The logic AND gate 438, having received an SFQ pulse at both inputs, can provide an intermediate SFQ pulse SFQ_{INT} at the output, thus corresponding to the first SFQ pulse SFQ₀. The intermediate SFQ pulse SFQ_{INT} is provided to the logic OR gate 440, which provides an output to the output JTL 442 that generates the output SFQ pulse SFQ_{AL} that is aligned to the clock signal (e.g., at) 90°.

In a second example, the RTZ pulse signal PLS arrives at the superconducting data alignment system 100 in the phase window of the second clock signal CLK₂ only (e.g., between 100° and) 260°. The RTZ pulse signal PLS thus provides the second signal current I_{SIG2} during the phase window of the second clock signal CLK₂ to trigger the second Josephson junction J₂ to generate a second signal SFQ pulse. The second signal SFQ pulse propagates through the JTLs 318 and 320 to be output as the second SFQ pulse SFQ₁₈₀. The second SFQ pulse SFQ₁₈₀ is thus input to the alignment circuit 400, and a first copy of the second SFQ pulse SFQ_{180_1} propagates through the JTLs 420, 422, and 424 of the second signal path 404 to the logic OR gate 440. The logic OR gate 440 thus provides the output SFQ pulse SFQ_{AL} to the output JTL 442 that propagates the output SFQ pulse SFQ_{AL} aligned to the clock signal (e.g., at 90°). A second copy of the second SFQ pulse SFQ_{180_2} also propagates through the JTLs 426 and 428; the logic OR gate 430; the JTL 432; and to the inverting JTL 434. The inverting JTL 434 thus inverts the second SFQ pulse SFQ₁₈₀ to an absence of a pulse, and thus a logic-0. As a result, no pulse propagates through the JTL 436 of the third signal path 406 to the logic AND gate 438. However, regardless of the signal in the third path 406, the absence of a signal in the first signal path 402 produces a logic-0 at the input the AND gate 438, thereby providing a logic-0 from the AND gate 438.

In a third example, the RTZ pulse signal PLS arrives at the superconducting data alignment system 100 in one of the two overlapping phase windows of the clock signals CLK₁ and CLK₂ (e.g., between 260° and 280° or between 80° and) 100°. The RTZ pulse signal PLS thus provides the first signal current I_{SIG1} and the second signal current I_{SIG2} during the overlapping phase windows to trigger the first and second Josephson junctions J₁ and J₂ to generate respective first and second signal SFQ pulses. The first and second signal SFQ pulses are provided to the JTLs 310 and 318 approximately concurrently.

In a first scenario of the third example, after the first and second Josephson junctions J₁ and J₂ trigger to generate the respective first and second signal SFQ pulses, the phase of the clock signal approaches the 90° phase increment first. In response, the first signal SFQ pulse propagates through the JTLs 310, 312, 314, and 316 to be output as the first SFQ pulse SFQ₀. At the time that the first signal SFQ pulse is propagated to the JTL 314 at the 270° phase increment, the second signal SFQ pulse is also propagated through the JTL 318. Thus, second signal SFQ pulse propagates through the JTLs 318 and 320 to be output as the second SFQ pulse SFQ₁₈₀. In the first scenario, the SFQ pulses SFQ₀ and SFQ₁₈₀ are output from the first and second coupling circuits 302 and 304 concurrently in time.

In the first scenario, the second SFQ pulse SFQ₁₈₀ is input to the alignment circuit 400, and a first copy of the second SFQ pulse SFQ₁₈₀_1 propagates through the JTLs 420, 422, and 424 of the second signal path 404 to the logic OR gate 440. The logic OR gate 440 thus provides the output SFQ pulse SFQ_{AL} to the output JTL 442 that propagates the output SFQ pulse SFQ_{AL} aligned to the clock signal (e.g., at) 90°. Additionally, the first SFQ pulse SFQ₀ is input to the alignment circuit 400 concurrently with the second SFQ pulse SFQ₁₈₀. The first SFQ pulse SFQ₀ propagates through the JTLs 408, 410, 412, 414, 416, and 418 to the logic AND gate 438. Concurrently, a second copy of the second SFQ pulse SFQ_{180_2} propagates through the JTLs 426 and 428; the logic OR gate 430; the JTL 432; and to the inverting JTL 434 of the third signal path 406. The inverting JTL 434 thus inverts the second copy of the second SFQ pulse SFQ_{180_2} to an absence of a pulse, and thus a logic-0. As a result, no pulse propagates through the JTL 436 of the third signal path 406 to the logic AND gate 438. Accordingly, the logic AND gate 438 rejects the first SFQ pulse SFQ₁₈₀ by providing no intermediate SFQ pulse SFQ_{INT} at the output of the logic AND gate 438. Accordingly, the alignment circuit 400 provides only a single output SFQ pulse SFQ_{AL}, despite the phase differences between the first and second SFQ pulses SFQ₀ and SFQ₁₈₀ generated by the first and second coupling circuits 302 and 304, respectively.

Additionally in the first scenario, after the second copy of the second SFQ pulse SFQ_{180_2} propagates through the JTLs 426 and 428 and the logic OR gate 430, a third copy of the second SFQ pulse SFQ_{180_3} is output from the logic OR gate 430 to the JTL 446 in the latch 444. The third copy of the second SFQ pulse SFQ_{180_3} thus propagates to the JTL 448 and the logic AND gate 450 (e.g., in combination with a logic-1 pulse provided from the inverting JTL 452), and propagates back to the logic OR gate 430. By providing the logic-1 to the logic OR gate 430, the latch 444 provides an indefinite logic-1 output from the logic OR gate 430 (e.g., an RTZ logic-1 pulse at every 270° of the clock signal). The indefinite logic-1 output from the logic OR gate 430 results in an indefinite logic-0 on the third signal path 406 to the input of the logic AND gate 438 (e.g., based on the inverting JTL 434). As a result, the logic AND gate 438 provides a logic-0 output indefinitely based on activation of the latch 444 in response to the second SFQ pulse SFQ₁₈₀. The duration of the logic-1 output from the logic OR gate 430, and thus the logic-0 output from the logic AND gate 438 remains indefinite until the reset signal RST is provided to the inverting JTL 452, at which the logic AND gate 450 provides a logic-0 output to disable the latch 444.

In a second scenario of the third example, after the first and second Josephson junctions J₁ and J₂ trigger to generate the respective first and second signal SFQ pulses, the phase of the clock signal approaches the 270° phase increment first. In response, the second signal SFQ pulse propagates through the JTLs 318 and 320 to be output as the second SFQ pulse SFQ₁₈₀. After the second SFQ pulse SFQ₁₈₀ is output from the second coupling circuit 304, and thus when the first copy of the second SFQ pulse SFQ_{180_1} is propagated by the JTL 420 and the second copy of the second SFQ pulse SFQ_{180_2} is propagated by the JTL 426 in the alignment circuit 400, the first signal SFQ pulse propagates through the JTL 310. The first signal SFQ pulse thus propagates through the JTLs 310, 312, 314, and 316 to be output as the first SFQ pulse SFQ₀. Accordingly, in the second scenario, the first SFQ pulse SFQ₀ is phase-delayed relative to the second SFQ pulse SFQ₁₈₀ by one complete clock cycle. Therefore, the first SFQ pulse SFQ₀ arrives as an input to the alignment circuit 400 one complete clock cycle delayed relative to the second SFQ pulse SFQ₁₈₀.

In the second scenario, the second SFQ pulse SFQ₁₈₀ is input to the alignment circuit 400 and a first copy of the second SFQ pulse SFQ_{180_1} propagates through the JTLs 420, 422, and 424 of the second signal path 404 to the logic OR gate 440. The logic OR gate 440 thus provides the output SFQ pulse SFQ_{AL} to the output JTL 442 that propagates the output SFQ pulse SFQ_{AL} aligned to the clock signal (e.g., at) 90°. Additionally, a second copy of the second SFQ pulse SFQ_{180_2} propagates through the JTLs 426 and 428 and to the logic OR gate 430. As demonstrated in the example of FIG. 4, the second copy of the SQF pulse SFQ₁₈₀ is output from the logic OR gate 430 to the JTL 432, and a third copy of the second SFQ pulse SFQ_{180_3} is output from the logic OR gate 430 to the JTL 446 in the latch 444. The second and third copies of the second SFQ pulse SFQ_{180_2} and SFQ_{180_3} thus propagate to the inverting JTL 434 and the JTL 448, respectively, at the 90° phase increment of the clock signal.

Continuing the second scenario of the third example, the second copy of the second SFQ pulse SFQ_{180_2} propagates from the JTL 432 to the inverting JTL 434 of the third signal path 406. The inverting JTL 434 thus inverts the second copy of the second SFQ pulse SFQ_{180_2} to an absence of a pulse, and thus a logic-0. As a result, no pulse propagates through the JTL 436 of the third signal path 406 to the logic AND gate 438 at a first 270° increment of the clock signal.

Continuing the second scenario of the third example, the first SFQ pulse SFQ₀ is input to the alignment circuit 400 and propagates through the JTL 408 concurrently when the second copy of the second SFQ pulse SFQ_{180_2} is inverted at the inverting JTL 434 and when the third copy of the second SFQ pulse SFQ_{180_3} propagates through the JTL 448. The first SFQ pulse SFQ₀ propagates through the JTLs 408, 410, 412, 414, 416, and 418 to the logic AND gate 438. Concurrently, the third copy of the second SFQ pulse SFQ_{180_3} propagates through the logic AND gate 450 (e.g., in combination with a logic-1 pulse provided from the inverting JTL 452), and propagates back to the logic OR gate 430. Similar to as described above in the first scenario of the third example, by providing the logic-1 to the logic OR gate 430, the latch 444 provides an indefinite logic-1 output from the logic OR gate 430, and thus an indefinite logic-0 on the third signal path 406 to the input of the logic AND gate 438 (e.g., based on the inverting JTL 434). As a result, the logic AND gate 438 provides a logic-0 output indefinitely based on activation of the latch 444 in response to the second SFQ pulse SFQ₁₈₀.

Continuing the second scenario of the third example, the first SFQ pulse SFQ₀ thus propagates through the JTLs 414, 416, and 418 to the logic AND gate 438 concurrently in phase with the third copy of the second SFQ pulse SFQ_{180_3} propagating through the JTL 432, the inverting JTL 434, and the JTL 436 to the logic AND gate 438. As a result, the latch 444 provides a phase-delay of one complete clock cycle of the third copy of the second SFQ pulse SFQ_{180_3} to phase-align the first SFQ pulse SFQ₀ and the third copy of the second SFQ pulse SFQ_{180_3} at the logic AND gate 438. Similar to as described above, because the latch 444 provides an indefinite logic-1 to the logic OR gate 430, the inverting JTL 434 provides an indefinite logic-0 from the third signal path 406 to the logic AND gate 438. Accordingly, the logic AND gate 438 rejects the first SFQ pulse SFQ₁₈₀, and all subsequent SFQ pulses on the first signal path 402 indefinitely, by providing no intermediate SFQ pulse SFQ_{INT} at the output of the logic AND gate 438. Accordingly, the alignment circuit 400 provides only a single output SFQ pulse SFQ_{AL}, despite the phase differences between the first and second SFQ pulses SFQ₀ and SFQ₁₈₀ generated by the first and second coupling circuits 302 and 304, respectively.

As an example, the clock signal that operates the superconducting data alignment system 100 (e.g., the clock signals CLK₁ and/or CLK₂) can be the same or operate from the same clock signal that provides the RTZ pulse signal PLS. Therefore, while the superconducting data alignment system is agnostic as to the timing of arrival the initial RTZ pulse signal PLS (e.g., with respect to the phase), subsequent RTZ pulse signal PLSs can be provided at approximately the same phase of the clock signals CLK₁ and CLK₂. Therefore, after the first RTZ pulse signal PLS is provided in one of the three examples described above, the subsequent RTZ pulse signal PLSs can be provided in the same one of the three examples as the first RTZ pulse signal PLS to a high probability. If timing between the circuit that provides the RTZ pulse signal PLS and the superconducting data alignment system 100 is somehow disrupted, then the reset signal RST can be provided to reset the latch 444 by propagating a logic-0 through the latch 444 (e.g., via the input of the logic AND gate 450). Accordingly, the superconducting data alignment system 100 can be initialized via the reset signal RST without powering down the superconducting data alignment system 100. Alternatively or additionally, the reset signal RST can be periodically provided to reset the latch 444.

FIG. 5 illustrates an example of a reciprocal quantum logic (RQL) superconducting circuit system 500. The RQL superconducting circuit system 500 includes a signal generating circuit 502, a superconducting data alignment system 504, and an RQL superconducting circuit 506. The RQL superconducting circuit system 500 is demonstrated as operating based on an RQL clock signal CLK_{RQL}, such that the RQL clock signal CLK_{RQL} is provided to each of the signal generating circuit 502, the superconducting data alignment system 504, and the RQL superconducting circuit 506. As an example, the RQL clock signal CLK_{RQL} can be arranged as an AC sinusoidal clock signal that includes an in-phase component and a quadrature-phase component to provide 90° circuit transitions.

The signal generating circuit 502 can be any of a variety of circuit systems that generates the RTZ pulse signal PLS as a current pulse. As an example, the signal generating circuit 502 can be an integrated superconducting circuit that is arranged as a self-contained IC (e.g., chip). Therefore, the signal generating circuit 502 can provide the RTZ pulse signal PLS across a passive transmission line (PTL) that propagates data without implementing the RQL clock signal CLK_{RQL}. As another example, the signal generating circuit 502 can be arranged as a classical computer system IC, such as operating in room-temperature space. Therefore, the signal generating circuit 502 can be configured to provide the RTZ pulse signal PLS on a microwave transmission line from the room-temperature operating environment to a cryogenic operating environment (e.g., less than 5 Kelvin).

The signal generating circuit 502 transmits the RTZ pulse signal PLS to the superconducting data alignment system 504 operating in the cryogenic temperature operating environment. The superconducting data alignment system 504 can correspond to the superconducting data alignment system 100 in the examples of FIGS. 1-4. Therefore, the superconducting data alignment system 504 can be configured to receive the RTZ pulse signal PLS and generate an output RQL pulse RQL_{AL} that is aligned to the RQL clock signal CLK_{RQL}. As an example, the clock signals CLK₁ and CLK₂ can correspond to opposite phases of one of the in-phase and quadrature-phase components of the RQL clock signal CLK_{RQL}. Therefore, the superconducting data alignment system 504 can align the data associated with the RTZ pulse signal PLS, the timing of which the superconducting data alignment system 504 is agnostic, to the RQL clock signal CLK_{RQL}.

The superconducting data alignment system 504 is configured to provide the output RQL pulse RQL_{AL} to the RQL superconducting circuit 506. The RQL superconducting circuit 506 can correspond to any of a variety of superconducting circuit systems that implements superconducting data in the form of RQL pulses, such as logic, memory, and data transfer. As an example, the RQL superconducting circuit 506 can be implemented as part of the IC that includes the superconducting data alignment system 504. Accordingly, the RQL superconducting circuit 506 can implement the data that is provided from the signal generating circuit 502 in the form of the RTZ pulse signal PLS via the phase-aligning interface provided by the superconducting data alignment system 504.

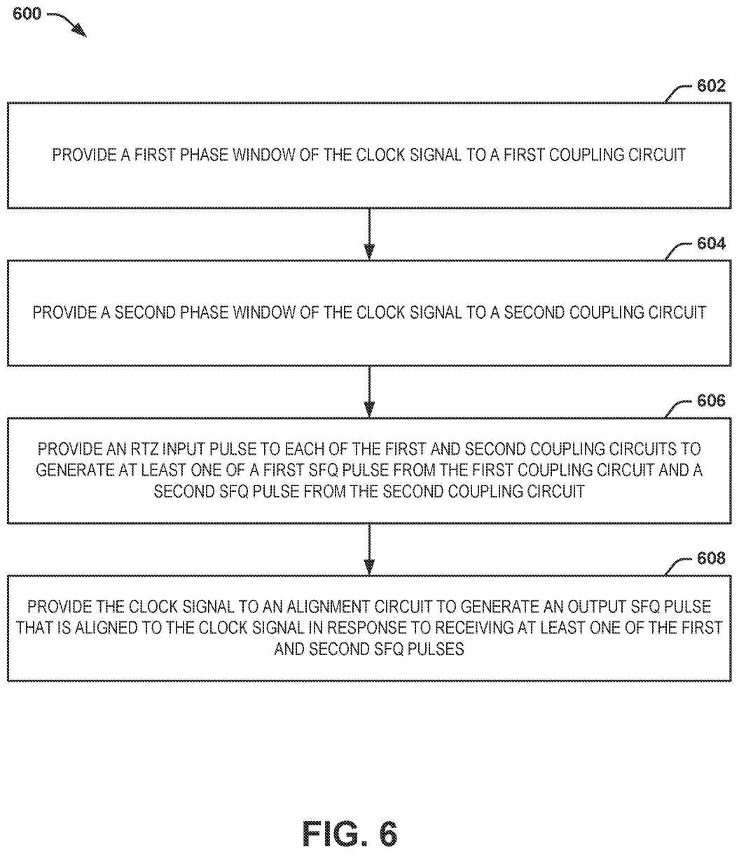

In view of the foregoing structural and functional features described above, a methodology in accordance with various aspects of the disclosure will be better appreciated with reference to FIG. 6. It is to be understood and appreciated that the method of FIG. 6 is not limited by the illustrated order, as some aspects could, in accordance with the present disclosure, occur in different orders and/or concurrently with other aspects from that shown and described herein. Moreover, not all illustrated features may be required to implement a methodology in accordance with an aspect of the present examples.

FIG. 6 illustrates an example of a method 600 method for aligning data to a defined phase of a clock signal (e.g., the clock signals CLK₁ and/or CLK₂) at an input of a superconducting circuit (e.g., the RQL superconducting circuit 506). At 602, a first phase window (e.g., of the first clock signal CLK₁) of the clock signal is provided to a first coupling circuit (e.g., the first coupling circuit 102). At 604, a second phase window (e.g., of the second clock signal CLK₂) of the clock signal is provided to a second coupling circuit (e.g., the second coupling circuit 104). The second phase window can be opposite in phase relative to the first phase window. At 606, an RTZ input pulse (e.g., the RTZ pulse signal PLS) is provided to each of the first and second coupling circuits to generate at least one of a first single flux quantum (SFQ) pulse (e.g., the first SFQ pulse SFQ₀) from the first coupling circuit and a second SFQ pulse (e.g., the second SFQ pulse SFQ₁₈₀) from the second coupling circuit. At 608, the clock signal is provided to an alignment circuit (e.g., the alignment circuit 106) to generate an output SFQ pulse (e.g., the output SFQ pulse SFQ_{AL}) that is aligned to the clock signal in response to receiving at least one of the first and second SFQ pulses.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A data alignment system comprising:
a first coupling circuit configured to receive a return-to-zero (RTZ) input pulse and to generate a first single flux quantum (SFQ) pulse in response to the RTZ input pulse being aligned with a phase window of a first clock signal;
a second coupling circuit configured to receive the RTZ input pulse and to generate a second SFQ pulse in response to the RTZ input pulse being aligned with a phase window of a second clock signal, the first and second clock signals being opposite in phase; and
an alignment circuit that is configured to generate an output SFQ pulse that is aligned to one of the first and second clock signals in response to receiving at least one of the first and second SFQ pulses.

2. The system of claim 1, wherein a portion of the phase windows of each of the first and second clock signals are overlapping with respect to each other.

3. The system of claim 2, wherein the phase window of the first clock signal comprises a first overlap portion and a second overlap portion, wherein the phase window of the second clock signal comprises a first overlap portion and a second overlap portion, wherein the first overlap portion of the phase window of the first clock signal overlaps the second overlap portion of the phase window of the second clock signal, wherein the second overlap portion of the phase window of the first clock signal overlaps the first overlap portion of the phase window of the second clock signal.

4. The system of claim 1, wherein the first coupling circuit comprises:
a first transformer configured to inductively couple the RTZ input pulse to generate a first inductive current; and
a first Josephson junction configured to trigger to generate the first SFQ pulse in response to the first inductive current and the phase window of the first clock signal,
wherein the second coupling circuit comprises:
a second transformer configured to inductively couple the RTZ input pulse to generate a second inductive current; and
a second Josephson junction configured to trigger to generate the second SFQ pulse in response to the second inductive current and the phase window of the second clock signal.

5. The system of claim 4, wherein the first coupling circuit further comprises a first plurality of Josephson transmission lines (JTLs) configured to propagate the first SFQ pulse based on at least one of the first and second clock signals, wherein the second coupling circuit further comprises a second plurality of JTLs configured to propagate the second SFQ pulse based on the at least one of the first and second clock signals, wherein the first plurality of JTLs is greater in quantity than the second plurality of JTLs to phase-delay the first SFQ pulse relative to the second SFQ pulse by one clock cycle from respective outputs of the first and second coupling circuits.

6. The system of claim 1, wherein the alignment circuit comprises:
a first signal path that comprises a first plurality of Josephson transmission lines (JTLs) that are configured to propagate the first SFQ pulse;
a second signal path that comprises a second plurality of JTLs that are configured to propagate the second SFQ pulse; and
a logic OR gate that is configured to generate the output SFQ pulse in response to at least one of the first and second SFQ pulses.

7. The system of claim 6, wherein the alignment circuit further comprises:
a third signal path that comprises a third plurality of JTLs that are configured to propagate the second SFQ pulse, wherein the third JTLs provide an approximately equal path-length of the second SFQ pulse as a path length of the first SFQ pulse along the first JTLs, wherein one of the third JTLs is arranged as an inverting JTL; and
a logic AND gate that is configured to generate an intermediate SFQ pulse in response to the first SFQ pulse and an absence of the second SFQ pulse, wherein the logic OR gate is configured to generate the output SFQ pulse in response to at least one of the intermediate SFQ pulse and the second SFQ pulse.

8. The system of claim 7, wherein the alignment circuit further comprises a latch coupled to the third signal path and being activated in response to the second SFQ pulse to provide a one period clock delay of the second SFQ pulse relative to the first SFQ pulse to the logic AND gate.

9. The system of claim 1, wherein the first SFQ pulse, the second SFQ pulse, and the output SFQ pulse are each provided as reciprocal quantum logic (RQL) pulses, wherein the first and second clock signals correspond to one of an in-phase component and a quadrature phase component of an RQL clock signal having opposite phases.

10. An RQL circuit system comprising the data alignment system of claim 9, wherein the RQL circuit system further comprises an RQL superconducting circuit that operates based on at the first and second clock signals that are arranged as an RQL clock signal, wherein the RQL superconducting circuit receives the output RQL pulse aligned to a defined phase of the RQL clock signal at an input.

11. A method for aligning data to a defined phase of a clock signal at an input of a superconducting circuit, the method comprising:
providing a first phase window of the clock signal to a first coupling circuit;
providing a second phase window of the clock signal to a second coupling circuit, the second phase window being opposite in phase relative to the first phase window;
providing a return-to-zero (RTZ) input pulse to each of the first and second coupling circuits to generate at least one of a first single flux quantum (SFQ) pulse from the first coupling circuit and a second SFQ pulse from the second coupling circuit; and
providing the clock signal to an alignment circuit to generate an output SFQ pulse that is aligned to the clock signal in response to receiving at least one of the first and second SFQ pulses.

12. The method of claim 11, wherein generating the first and second phase windows comprises generating the first and second phase windows of the clock signal such that a portion of each of the first and second phase windows associated with the clock signal are overlapping with respect to each other.

13. The method of claim 11, further comprising providing the clock signal to the first and second coupling circuits to phase-delay the first SFQ pulse relative to the second SFQ pulse by one clock cycle from respective outputs of the first and second coupling circuits via a plurality of Josephson transmission lines (JTLs).

14. The method of claim 13, further comprising delaying the second SFQ pulse relative to the first SFQ pulse by the one clock cycle in the alignment circuit to provide at least one logic operation on the first and second SFQ pulses to generate the output SFQ pulse.

15. The method of claim 11, wherein providing the clock signal to the alignment circuit comprises:
providing the clock signal to propagate the first SFQ pulse along a first signal path that comprises a first plurality of Josephson transmission lines (JTLs);
providing the clock signal to propagate the second SFQ pulse along a second signal path that comprises a second plurality of JTLs; and
providing the clock signal to a logic OR gate that is configured to generate the output SFQ pulse in response to at least one of the first and second SFQ pulses.

16. A reciprocal quantum logic (RQL) circuit system comprising:
a data alignment system, the data alignment system comprising:
a first coupling circuit configured to receive a return-to-zero (RTZ) input pulse and to generate a first RQL pulse in response to the RTZ input pulse being aligned with a first phase window of an RQL clock signal;
a second coupling circuit configured to receive the RTZ input pulse and to generate a second RQL pulse in response to the RTZ input pulse being aligned with a second phase window of the RQL clock signal, the first and second phase windows being opposite in phase; and
an alignment circuit that is configured to generate an output RQL pulse that is aligned to the RQL clock signal in response to receiving at least one of the first and second RQL pulses; and
an RQL superconducting circuit that operates based on the RQL clock signal, wherein the RQL superconducting circuit receives the output RQL pulse aligned to a defined phase of the RQL clock signal at an input.

17. The system of claim 16, wherein a portion of the first and second phase windows of the RQL clock signal are overlapping with respect to each other.

18. The system of claim 16, wherein the first coupling circuit comprises:
a first transformer configured to inductively couple the RTZ input pulse to generate a first inductive current;
a first Josephson junction configured to trigger to generate the first RQL pulse in response to the first inductive current and the first phase window of the RQL clock signal; and
a first plurality of Josephson transmission lines (JTLs) configured to propagate the first RQL pulse based on the RQL clock signal,
wherein the second coupling circuit comprises:
a second transformer configured to inductively couple the RTZ input pulse to generate a second inductive current;
a second Josephson junction configured to trigger to generate the second RQL pulse in response to the second inductive current and the second phase window of the RQL clock signal; and
a second plurality of JTLs configured to propagate the second RQL pulse based on the RQL clock signal, wherein the first plurality of JTLs is greater in quantity than the second plurality of JTLs to phase-delay the first RQL pulse relative to the second RQL pulse by one clock cycle from respective outputs of the first and second coupling circuits.

19. The system of claim 16, wherein the alignment circuit comprises:
a first signal path that comprises a first plurality of Josephson transmission lines (JTLs) that are configured to propagate the first RQL pulse;
a second signal path that comprises a second plurality of JTLs that are configured to propagate the second RQL pulse;
a third signal path that comprises a third plurality of JTLs that are configured to propagate the second RQL pulse, wherein the third JTLs provide an approximately equal path-length of the second RQL pulse as a path length of the first RQL pulse along the first JTLs, wherein one of the third JTLs is arranged as an inverting JTL;
a logic AND gate that is coupled to the first and third signals paths and which is configured to generate an intermediate RQL pulse in response to the first RQL pulse and an absence of the second RQL pulse; and
a logic OR gate that is coupled to the logic AND gate and the second signal path, the logic OR gate being configured to generate the output RQL pulse in response to at least one of the first RQL pulse and the intermediate RQL pulse.

20. The system of claim 19, wherein the alignment circuit further comprises a latch coupled to the third signal path and being activated in response to the second RQL pulse to provide a one period clock delay of the second RQL pulse relative to the first RQL pulse to the logic AND gate.
